(19) United States
(12) Patent Application Publication
(10) Pub. No.: US 2017/0178868 A1
(43) Pub. Date: Jun. 22, 2017

(54) UPPER ELECTRODE FOR PLASMA PROCESSING APPARATUS AND PLASMA PROCESSING APPARATUS HAVING THE SAME

(71) Applicant: Samsung Electronics Co., Ltd., Suwon-si (KR)

(72) Inventors: Seong Moon HA, Seoul (KR); Kyung Sun KIM, Suwon-si (KR); Kang Min JEON, Hwaseong-si (KR)

(21) Appl. No.: 15/248,326

(22) Filed: Aug. 26, 2016

(30) Foreign Application Priority Data
Dec. 18, 2015 (KR) 10-2015-0181508

(51) Int. Cl. H01J 37/32

(52) U.S. Cl. CPC H01J 37/32532; H01J 37/3244; H01J 2237/334

(57) ABSTRACT

An upper electrode for a plasma processing apparatus includes a body portion having a plurality of through-holes, a showerhead disposed below the body portion and having a plurality of jet holes connected to the plurality of through-holes, and a buffer layer interposed between the body portion and the showerhead.

### CROSS-REFERENCE TO RELATED APPLICATION(S)

This application claims benefit of priority to Korean Patent Application No. 10-2015-0181508 filed on Dec. 18, 2015 in the Korean Intellectual Property Office, the disclosure of which is incorporated herein by reference in its entirety.

### BACKGROUND

The present exemplary implementations of the herein to an upper electrode for a plasma processing apparatus and a plasma processing apparatus having the same.

In general, plasma refers to a state of matter formed by an ionized gas containing an ion, an electron, a radical, and the like, and may be generated by significantly increasing a temperature in a chamber, or applying a strong electric field or a radio-frequency (RF) electromagnetic field to a gas.

Plasma processing apparatuses refer to devices in which a reactant is converted into a plasma state to be deposited on a semiconductor substrate or a semiconductor substrate is cleaned, ashed, or etched using a reactant in a plasma state. Plasma processing apparatuses include a lower electrode installed within a chamber and provided with a substrate mounted thereon, and an upper electrode installed in an upper portion of the chamber to face the lower electrode.

As levels of difficulty in undertaking plasma processes have increased, there has been a rising demand for high RF power. However, this results in a problem in that an upper electrode is exposed to a high temperature and therefore reaches an excessively high temperature level. The excessive high temperature level may cause the lifespan of the upper electrode to be shortened and a difference in the degree of thermal expansion between the showerhead and peripheral parts may cause damage.

### SUMMARY

An aspect of a present exemplary implementation of the herein described subject matter may provide a scheme in which an upper electrode is maintained at a proper temperature.

According to an aspect of the present exemplary implementation, an upper electrode for a plasma processing apparatus may include a body portion having a plurality of through-holes, a showerhead disposed below the body portion and having a plurality of jet holes connected to the plurality of through-holes, and a buffer layer interposed between the body portion and the showerhead.

The buffer layer may include a fluoride resin. The buffer layer may include a pluralityof connection holes interconnecting the plurality of through-holes and the plurality of j et holes. The buffer layer may be coplanar with side surfaces of the body portion and the showerhead.

The showerhead may be coupled to the body portion to be detachable therefrom. The showerhead may include a material such as silicon (Si) or silicon carbide (SiC).

The body portion may have a cooling unit disposed therein. The body portion may have a heating unit disposed therein. The body portion may include a material such as a metal including aluminum (Al).

The body portion may include a first body portion having a plurality of first through-holes, a second body portion disposed below the first body portion and having a plurality of second through-holes connected to the plurality of the first through-holes, and a third body portion disposed below the second body portion and having a plurality of third through-holes connected to the plurality of the second through-holes.

According to an aspect of another exemplary implementation, a plasma processing apparatus may include a chamber, a lower electrode disposed in a lower portion of the chamber, and an upper electrode disposed in an upper portion of the chamber. The upper electrode may include a body portion having the plurality of through-holes, the showerhead disposed below the body portion and having the plurality of jet holes connected to the plurality of through-holes, and the buffer layer interposed between the body portion and the showerhead.

The buffer layer may include a fluoride resin. The buffer layer may include a plurality of connection holes interconnecting the plurality of through-holes and the plurality of jet holes.

The plasma processing apparatus may further include a process gas supply unit connected to the upper electrode. The process gas supply unit may supply CF-type gas to the chamber.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic cross-sectional view of a plasma processing apparatus according to an exemplary implementation of the herein described subject matter;

FIG. 2 is a schematic cross-sectional view of an upper electrode of the plasma processing apparatus illustrated in FIG. 1;

FIG. 3 is a schematic exploded cross-sectional view of the upper electrode illustrated in FIG. 2;

FIGS. 4A and 4B are respective enlarged cross-sectional views of contact areas between a showerhead and a third body portion; and

FIG. 5 is an enlarged schematic cross-sectional view illustrating a state in which heat of the showerhead is transferred.

### DETAILED DESCRIPTION

The present disclosure now will be described more fully hereinafter with reference to the accompanying drawings, in which various exemplary implementations are shown. The invention may, however, be embodied in many different forms and should not be construed as limited to the exemplary implementations set forth herein. These example exemplary implementations are just that—examples—and many implementations and variations are possible that do not require the details provided herein. It should also be emphasized that the disclosure provides details of alternative examples, but such listing of alternatives is not exhaustive. Furthermore, any consistency of detail between various exemplary implementations should not be interpreted as requiring such detail—it is impracticable to list every possible variation for every feature described herein. The language of the claims should be referenced in determining the requirements of the invention.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present. Other words used to describe the relationship between elements should be interpreted in a like fashion (e.g., “between” versus “directly between,” “adjacent” versus “directly adjacent,” etc.).

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other. Spatially relative terms, such as “above,” “upper,” “below,” and “lower” and the like, may be used herein for ease of description to describe one element's relationship to another element(s) as shown in the figures. It will be understood that the spatially relative terms are intended to encompass different orientations of the device in use or operation in addition to the orientation depicted in the figures. For example, if the device in the figures is turned over, elements described as “above,” or “upper” other elements would then be oriented “below,” or “lower” the other elements or features. Thus, the term “above” can encompass both the above and below orientations depending on a particular direction of the figures. The device may be otherwise oriented (rotated 90 degrees or at other orientations) and the spatially relative descriptors used herein may be interpreted accordingly.

The terminology used herein is for the purpose of describing particular exemplary implementations only and is not intended to be limiting of the invention. As used herein, the singular forms “a”, “an” and “the” are intended to include the plural forms as well, unless the context clearly indicates otherwise. As used herein, the term “and/or” includes any and all combinations of one or more of the associated listed items and may be abbreviated as “/”.

Embodiments described herein will be described referring to plan views and/or cross-sectional views by way of ideal schematic views. Accordingly, the exemplary views may be modified depending on manufacturing technologies and/or tolerances. Therefore, the disclosed exemplary implementations are not limited to those shown in the views, but include modifications in configuration formed on the basis of manufacturing processes. Therefore, regions exemplified in figures may have schematic properties, and shapes of regions shown in figures may exemplify specific shapes of regions of elements to which aspects of the invention are not limited.

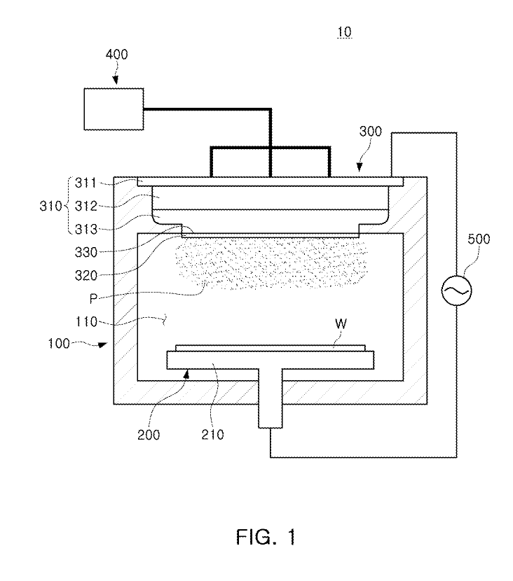

FIG. 1 is a schematic cross-sectional view of a plasma processing apparatus according to an example exemplary implementation.

With reference to FIG. 1, a plasma processing apparatus 10 may include chamber 100, lower electrode 200 disposed in a lower portion of chamber 100, and upper electrode 300 disposed in an upper portion of chamber 100. The plasma processing apparatus 10 may further include process gas supply unit 400 connected to upper electrode 300.

The chamber 100 may have internal space 110 having a predetermined size, and may be formed of a material having excellent wear resistance and corrosion resistance. The chamber 100 may keep internal space 110 airtight or in a vacuum in a plasma processing process, such as an etching process.

The lower electrode 200 may be disposed in a lower portion of internal space 110 within chamber 100. For example, lower electrode 200 may include mounting table 210 formed of a material such as aluminum, or the like. A semiconductor wafer (W) may be disposed, for treatment, on an upper surface of mounting table 210.

The upper electrode 300 may be disposed in an upper portion of chamber 100 to face lower electrode 200 while being spaced apart therefrom by a predetermined interval. The upper electrode 300 may be connected to process gas supply unit 400 which may supply process gas, such as CF-type gas, to chamber 100 through upper electrode 300.

The upper electrode 300 and lower electrode 200 may be connected to power supply 500, and plasma (P) formed of the process gas may be generated in a space between upper electrode 300 and lower electrode 200.

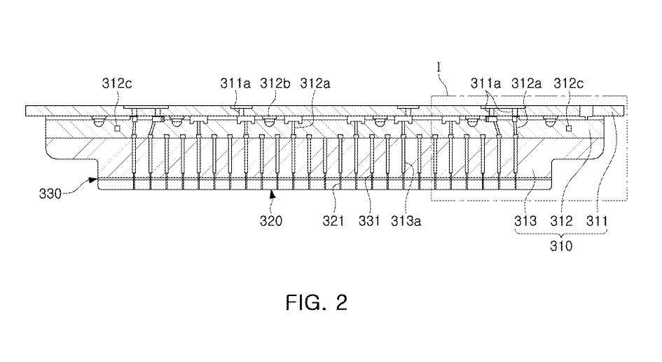

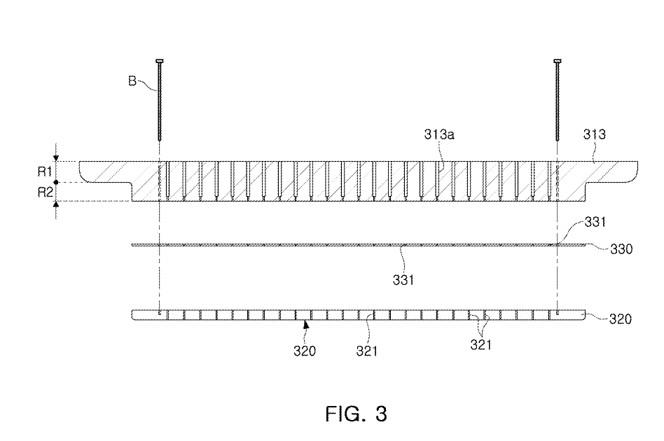

With reference to FIGS. 2 and 3, the upper electrode will be described. FIG. 2 is a schematic cross-sectional view of the upper electrode of the plasma processing apparatus illustrated in FIG. 1, while FIG. 3 is a schematic exploded cross-sectional view of the upper electrode illustrated in FIG. 2.

With reference to FIGS. 2 and 3, upper electrode 300 may include body portion 310, showerhead 320, and buffer layer 330.

The body portion 310 may include first body portion 311, second body portion 312, and third body portion 313. The body portion 310 may have a structure in which first body portion 311 and second body portion 312 are sequentially stacked and connected to each other on third body portion 313.

For example, first body portion 311 may be disc-shaped, and may have a plurality of first through-holes 311a penetrating through an upper surface and a lower surface.

The second body portion 312 may be disposed below first body portion 311. The second body portion 312 may be disc-shaped. In this case, a diameter of second body portion 312 may be smaller than that of first body portion 311. Thus, there may be a step portion between second body portion 312 and first body portion 311.

The second body portion 312 may have a plurality of second through-holes 312a connected to the plurality of first through-holes 311a. The plurality of second through-holes 312a may be more in number and smaller in size compared to the plurality of first through-holes 311a.

The second body portion 312 may include cooling unit 312b disposed therein. For example, cooling unit 312b may include a refrigerant path through which a refrigerant flows. The cooling unit 312b may externally release heat transferred from showerhead 320 which will be described subsequently. Thus, showerhead 320 may be prevented from being excessively heated when in use.

In addition, second body portion 312 may include heating unit 312c disposed therein. For example, heating unit 312c may have an electric heater which prevents the temperature of upper electrode 300 including showerhead 320 from falling below a required operating temperatures including the operating temperature for an idle mode.

The cooling unit 312b and heating unit 312c selectively operate in accordance with need and may control the temperature of upper electrode 300 including showerhead 320.

The example exemplary implementation illustrates a state in which cooling unit 312b and heating unit 312c are mounted in second body portion 312, but the present exemplary implementation is not limited thereto. For example, cooling unit 312b may be mounted in the first body portion 311.

The third body portion 313 may be disposed below second body portion 312, and may include a plurality of third through-holes 313a connected to the plurality of second through-holes 312a.

The third body portion 313 may include first region R1 being coplanar with a side surface of second body portion 312 and second region R2 being coplanar with a side surface of showerhead 320, and may have a step portion between first region R1 and second region R2.

The upper electrode 300 may be fixed to the upper portion of chamber 100 through the step portion included in the third body portion 313 and the step portion formed between the second body portion 312 and the first body portion 311. The upper electrode 300 may have an outer surface that comprises an upper portion of the chamber 100.

The body portion 310 may be formed of a material such as a metal, for example, aluminum (Al). However, the material of the body portion 310 is not limited thereto, and body portion 310 may be formed of a different solid material.

Furthermore, first body portion 311, second body portion 312, and third body portion 313 may be coupled to be detachable from each other, such as through a screw tightening method using a fastening bolt.

Although body portion 310 is exposed to high-temperature plasma, if a problem caused by thermal fatigue occurs in a single portion, the problem may be easily resolved by replacing only the problematic portion because body portion 310 has first body portion 311, second body portion 312, and third body portion 313 are provided to be detachable with respect to each other. Thus, since the body portion 310 is easier to maintain and repair compared to a structure having an integral-type body portion, and the entire body portion does not need to be replaced, the body portion 310 may effect cost savings.

The showerhead 320 may be disposed below third body portion 313. In addition, showerhead 320 may be exposed to plasma generated in a space between upper electrode 300 and lower electrode 200.

The showerhead 320 is an element directly exposed to high-temperature plasma in a structure in contact with upper electrode 300, and thus, may be formed of a material resistant to high temperatures. As a material of the showerhead 320, silicon (Si), silicon carbide (SiC), or the like may be used.

The showerhead 320 may include a plurality of jet holes 321 connected to the plurality of third through-holes 313a.

The showerhead 320 may be a consumable portion, distinct from the body portion 310. Thus, showerhead 320 should be easy to replace. For example, showerhead 320 may be coupled to third body portion 313 through a fastening bolt (B) to be detachable therefrom.

The buffer layer 330 may be interposed between body portion 310 and showerhead 320. The buffer layer 330 may increase a mutual contact area by filling a gap which may occur between body portion 310 and showerhead 320. The increase in the contact area may effectively improve heat dissipation of showerhead 320.

As illustrated in FIG. 2, buffer layer 330 may be provided to be coplanar with body portion 310. More particularly, with side surfaces of third body portion 313 and showerhead 320.

The buffer layer 330 may have a plurality of connection holes 331 interconnecting the plurality of third through-holes 313a and the plurality of jet holes 321.

The buffer layer 330 may be formed using a material having excellent thermal and chemical resistance. For example, buffer layer 330 may be formed using a polymer material (such as a thermoplastic polymer) having excellent workability, but is not limited thereto. The buffer layer 330 may include, for example, a fluoride resin. Examples of a fluoride resin which may be used in buffer layer 330 may include polytetra fluoroethylene (PTFE), polychlorotrifluoroethylene (PCTFE), polyvinylidene difluoride (PVDF), polyvinyl fluoride (PVF), and the like. The buffer layer 330 may be deformable so that its outer surfaces mold to the surfaces of third body portion 313 and showerhead 320. The buffer layer 330 may have a Young's modulus of about 0.5 GPa or less, or about 1 GPa or less. The buffer layer 330 may have a yield strength of about 25 MPa or less, or about 50 MPa or less. The buffer layer 330 may have elasticity in a range of about 300% to about 350%, a tensile strength in a range of about 25 MPa to about 30 MPa, a compressive strength in a range of about 15 MPa to 20 MPa, Rockwell hardness (R scale) of about R50, a thermal conductivity of about 0.19 W/mk.

The buffer layer 330 may be provided on a surface of third body portion 313 or a surface of showerhead 320 through a coating method. For example, the surface of third body portion 313 may be anodized. In this case, third body portion 313 may have a surface having microscale roughness. The rough surface may cause a relatively large amount of gaps, such as voids, when joined to the surface of showerhead 320. According to the example exemplary implementation, buffer layer 330 may be coated on the anodized surface of third body portion 313 and may increase contact area to facilitate heat transfer when the rough surface of third body portion 313 is joined to showerhead 320. The buffer layer 330 may be a relatively thin coating layer formed through coating.

For example, buffer layer 330 may cover the anodized surface of third body portion 313 through a large-area coating method, such as spray coating or slit coating of fluoride resin.

In a similar manner, buffer layer 330 formed through coating may fill the entirety of a relatively large amount of microscale unevenness portions formed on the surface of third body portion 313 to have a required thickness. In other words, spraying a fluoride resin on the surface of third body portion 313 may lead to the large amount of microscale unevenness portions formed on the surface of third body portion 313 being entirely filled, and to easy forming of buffer layer 330 having a required thickness by controlling an amount of fluoride resin sprayed.

The buffer layer 330 may also be attached to the surface of third body portion 313 or showerhead 320 in a form of a thin film.

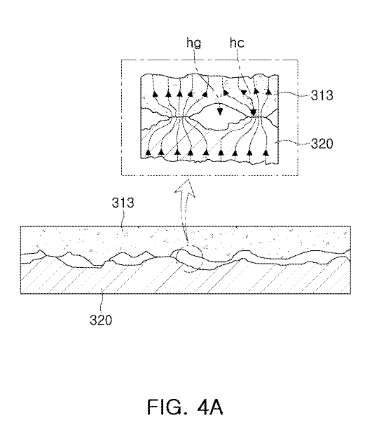

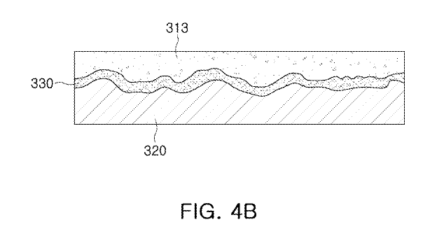

FIGS. 4A and 4B are respective enlarged cross-sectional views of the contact area between showerhead 320 and third body portion 313.

FIG. 4A is an enlarged schematic cross-sectional view of a direct contact area between showerhead 320 and third body portion 313.

As illustrated in FIG. 4A, microscale unevenness or roughness may be formed on the surfaces of third body portion 313 and showerhead 320 due to an error in a manufacturing process or technological limitations. Thus, in the case that the surfaces are close to each other, voids by which the surfaces are separated from each other, for example, not in contact with each other, may be formed. The voids may reduce thermal conductivity in transferring heat from showerhead 320 to body portion 310.

FIG. 4B is an enlarged schematic cross-sectional view illustrating a contact area of buffer layer 330 interposed between showerhead 320 and third body portion 313.

As illustrated in FIG. 4B, buffer layer 330 may be attached to opposing surfaces of showerhead 320 and third body portion 313. The contact structure of buffer layer 330 may prevent thermal conductivity from decreasing by preventing a void from being formed and/or reducing the number of voids formed in the contact area between showerhead 320 and third body portion 313, thereby significantly increasing an effective contact area. Thus, a proper temperature of showerhead 320 may be maintained.

With reference to FIG. 4A, a conditional condition regarding a heat transfer coefficient h at a contact area may be illustrated as below.

h=hc+hg

In the equation, ‘hc’ is a heat transfer coefficient through contact between solid objects, and ‘hg’ is a heat transfer coefficient in a void. Thus, in order to increase ‘h’, the overall heat transfer coefficient, a value of ‘hc’ already having a relatively high heat transfer coefficient may be increased.

An equation for ‘hc’ is as below.

hc=1.25kₛ(m/σ)(P/H_{c})^{0.95}

In the equation, ‘kₛ’ may be a harmonic mean thermal conductivity for two solids, ‘m’ may be a fin performance parameter, ‘σ’ may be the effective rms surface roughness of the two materials, ‘P’ may be contact pressure, and ‘H_{c}’, may be hardness.

In other words, ‘hc’, a heat transfer coefficient between showerhead 330 and third body portion 313, which represents contact between solid objects, not between voids, is in inverse proportion to hardness. Thus, as the hardness is decreased, ‘hc’ may be increased.

As illustrated in FIG. 4A, a hardness value (Vickers hardness, Hv) of Al material surface-treated on third body portion 313 through hard anodization is approximately 2,000. On the other hand, in the case that a Teflon coating is applied as buffer layer 330 as illustrated in FIG. 4B, a hardness value decreases to approximately 420. A heat transfer coefficient, ‘hc’, calculated by substituting respective hardness values is as below.

TABLE 1

| | No Buffer Layer | Buffer Layer |
|---|---|---|
| Classification | Interposed | Interposed |
| Hc | 25 W/m²K | 100 W/m²K |

In the case that a buffer layer is interposed as shown in Table 1, a heat transfer coefficient may be increased by about four times. Thus, since a case in which a buffer layer is interposed has an entirely increased heat transfer coefficient on a contact area compared to a case in which a buffer layer is not interposed, a temperature of showerhead 320 may be transferred rapidly.

In the meantime, with reference to the results, in the case that buffer layer 330 is not interposed between showerhead 320 and third body portion 313 as illustrated in FIG. 4A and the case that buffer layer 330 is interposed therebetween as illustrated in FIG. 4B, cooling performance has been determined by measuring temperatures of respective upper electrodes 300.

The determination of cooling performance was implemented in a manner in which a temperature of a showerhead while a RF power of 8300 W is applied for 750 seconds as a processing condition could be measured.

TABLE 2

| | No Buffer Layer | Buffer Layer |
|---|---|---|
| Classification | Interposed | Interposed |
| Temperature of | 220° C. | 170° C. |
| Showerhead | | |

With reference to Table 2, since voids occurring on a contact area between showerhead 320 and third body portion 313 decreases thermal conductivity, a temperature of showerhead 320 is relatively high at 220° C. in a state in which buffer layer 330 is not interposed. As heat is transferred through a contacted portion between showerhead 320 and third body portion 313 except the void, a contact area therebetween through which heat may be transferred was further decreased due to the occurrence of the voids.

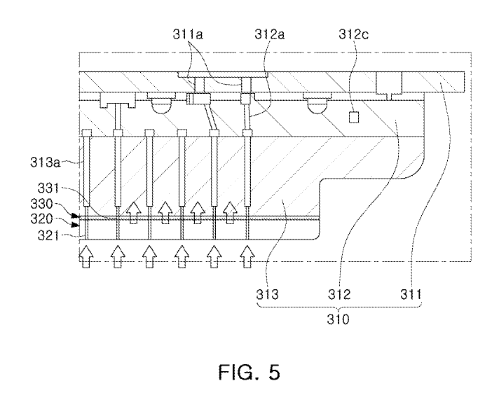

In a state in which buffer layer 330 is interposed, since a non-contact portion caused by a void does not occur, a structure in which an effective contact area is increased may be provided. In other words, as illustrated in FIG. 5, showerhead 320 heated by high-temperature plasma may enable heat (marked by arrows) to be transferred to third body portion 313 through the entire contact area between showerhead 320 and third body portion 313. Thus, it could be confirmed that the temperature of showerhead 320 was decreased to 170° C.

In addition, it can be understood that since a heat transfer coefficient in a state in which buffer layer 330 is interposed is relatively high, the heat of showerhead 320 was rapidly transferred to body portion 310, and thus, the temperature of showerhead 320 was further decreased.

It could be confirmed that as buffer layer 330 was interposed between showerhead 320 and third body portion 313, the temperature of showerhead 320 was further decreased by around 25%, thereby providing cooling performance.

As set forth above, according to an example exemplary implementations, an upper electrode for a plasma processing apparatus in which a temperature of the upper electrode may be properly maintained and a plasma processing apparatus including the same may be provided.

While example exemplary implementations have been shown and described above, it will be apparent to those skilled in the art that modifications and variations could be made without departing from the scope of the present inventive concept as defined by the appended claims.

What is claimed is:

1. An upper electrode for a plasma processing apparatus comprising:
a body portion having a plurality of through-holes;
a showerhead disposed below the body portion and having a plurality of jet holes connected to the plurality of through-holes; and
a deformable buffer layer interposed between the body portion and the showerhead.

2. The upper electrode for a plasma processing apparatus of claim 1, wherein the buffer layer includes a fluoride resin.

3. The upper electrode for a plasma processing apparatus of claim 2, wherein the fluoride resin includes at least one of polytetra fluoroethylene (PTFE), polychlorotrifluoroethylene (PCTFE), polyvinylidene difluoride (PVDF), and polyvinyl fluoride (PVF).

4. The upper electrode for a plasma processing apparatus of claim 1, wherein the buffer layer is provided as a coating layer coated on a surface of the body portion.

5. The upper electrode for a plasma processing apparatus of claim 1, wherein the buffer layer includes a plurality of connection holes interconnecting the plurality of through-holes and the plurality of jet holes.

6. The upper electrode for a plasma processing apparatus of claim 1, wherein the showerhead is coupled to the body portion to be detachable therefrom.

7. The upper electrode for a plasma processing apparatus of claim 1, wherein the showerhead includes comprises at least one of silicon (Si) or silicon carbide (SiC).

8. The upper electrode for a plasma processing apparatus of claim 1, wherein the body portion comprises at least one of a cooling unit and a heating unit disposed therein.

9. The upper electrode for a plasma processing apparatus of claim 1, wherein the body portion includes aluminum (Al).

10. The upper electrode for a plasma processing apparatus of claim 1, wherein the body portion includes a first body portion having a plurality of first through-holes, a second body portion disposed below the first body portion and having a plurality of second through-holes connected to the plurality of the first through-holes, and a third body portion disposed below the second body portion and having a plurality of third through-holes connected to the plurality of the second through-holes.

11. A plasma processing apparatus comprising:
a chamber;
a lower electrode disposed in a lower portion of the chamber; and
an upper electrode disposed in an upper portion of the chamber,
wherein the upper electrode includes:
a body portion having a plurality of through-holes;
a showerhead disposed below the body portion and having a plurality of jet holes connected to the plurality of through-holes; and
a deformable buffer layer interposed between the body portion and the showerhead.

12. The plasma processing apparatus of claim 11, wherein the buffer layer includes a fluoride resin.

13. The plasma processing apparatus of claim 11, wherein the buffer layer is provided as a coating layer coated on a surface of the body portion.

14. The plasma processing apparatus of claim 11, further comprising a process gas supply unit connected to the upper electrode.

15. The plasma processing apparatus of claim 14, wherein the process gas supply unit supplies CF-type gas to the chamber.

16. A plasma processing apparatus for use in semiconductor fabrication, comprising:
a chamber;
a lower electrode assembly disposed in a lower portion of the chamber and including a lower electrode and a mounting table for receiving a semiconductor wafer;
an upper electrode assembly disposed in an upper portion of the chamber and including an upper electrode mounted on a body portion having a plurality of through-holes,
a showerhead disposed below the body portion and having a plurality of jet holes connected to the plurality of through-holes; and
a deformable buffer layer interposed between the body portion and the showerhead, wherein the deformable buffer layer has a yield strength of 1 GPa or less.

17. The plasma processing apparatus of claim 16, wherein said body portion being comprised of at least two detachable parts and said showerhead is detachable from said body portion.

18. The plasma processing apparatus of claim 17, wherein the buffer layer is provided as a coating layer coated on a surface of the body portion and wherein the buffer layer includes a plurality of connection holes interconnecting the plurality of through-holes and the plurality of jet holes.

19. The plasma processing apparatus of claim 16, wherein the deformable buffer layer includes a fluoride resin.

20. The plasma processing apparatus of claim 16, wherein the showerhead comprises at least one of silicon (Si) or silicon carbide (SiC).
